(19) United States
(12) Patent Application Publication
(10) Pub. No.: US 2012/0255764 A1
(43) Pub. Date: Oct. 11, 2012

(54) PRINTED CIRCUIT BOARD AND MANUFACTURING METHOD THEREOF

(75) Inventors: Jin Su Kim, Gyeonggi-do (KR); Myoung Hwa Nam, Gyeonggi-do (KR); Yeong Uk Seo, Incheon (KR); Chi Hee Ahn, Gyeonggi-do (KR)

(73) Assignee: LG INNOTEK CO., LTD., Seoul (KR)

(21) Appl. No.: 13/500,754

(22) PCT Filed: Aug. 5, 2010
(86) PCT No.: PCT/KR2010/005124

§ 371 Date: Jun. 22, 2012

(30) Foreign Application Priority Data
Oct. 8, 2009 (KR) 10-2009-0095840

(51) Int. Cl. H05K 3/00; G03F 7/20; H05K 1/02

(52) U.S. Cl. 174/251; 156/60; 216/13; 156/150; 156/247; 430/319

(57) ABSTRACT

An embedded printed circuit board and a manufacturing method thereof are provided. The manufacturing method includes a first step of forming a first insulating layer having a seed layer formed on one side thereof and at least. one metal pattern embedded therein and a second step of laminating the first insulating layer and a base substrate with an inner circuit having a second insulating layer interposed between the first insulating layer and the base substrate. Accordingly, a printed circuit board with a circuit embedded in an insulating layer is provided, and thus a high-density and high-reliability printed circuit board can be achieved. Furthermore, since the printed circuit board is manufactured using a mold, a circuit manufacturing process for embedding, a process for forming a seed layer and a complicated process such as surface grinding are omitted so as to simplify the manufacturing process.

### TECHNICAL FIELD

The present invention relates to a printed circuit board having a circuit pattern embedded therein and a manufacturing method thereof.

### BACKGROUND ART

Techniques of embedding vias and patterns in insulating layers have been widely used to improve the reliability of a high-density pattern. There are two methods of manufacturing an embedded printed circuit board. The first method forms a circuit pattern first, embeds the circuit pattern in an insulating layer and removes a seed layer used to form the circuit pattern to obtain a final circuit. The second method manufactures a mold with a positive pattern corresponding to a circuit shape, forms a negative pattern in an insulating layer using the mold, fills the negative pattern with a conductive material and grinds the surface of the insulating layer to achieve a final circuit.

FIG. 1 illustrates the former method that forms a circuit pattern and embeds the circuit pattern in an insulating layer.

Specifically, a core layer 10 with a via-hole 14 and an inner circuit 12 is prepared (a), and two substrates each being manufactured by forming a circuit pattern 22 on a seed layer 20 with a carrier film 24 attached onto the backside thereof are provided (b). The two substrates are placed on both sides of the core layer 10 and pressed, and then the carrier film is removed (c). Regions at which via-holes will be formed are defined through DFR exposure (d) and portions of the seed layer 20 corresponding to the regions are selectively removed (e). Then, surface copper plating is performed on the removed portions of the seed layer 20 (f), and predetermined portions of the seed layer 20 is selectively removed using DFR to form via-holes 60 (g). The DRF is stripped off and solder paste is coated (h) to form a connecting via 52 and a connecting pad 62 (i).

This method has to manufacture the substrates with the circuit pattern 22 formed thereon in advance in order to form the embedded pattern, as described above, and thus the manufacturing process becomes complicated and productivity is decreased.

Referring to FIG. 2, an insulating layer 2 on which an insulating resin is deposited and a metal mold 1 are provided (a), and the metal mold 1 is pressed against the insulating layer 2 (b). Then, the metal mold is removed (c) and a via-hole 4 is formed in the insulating resin (d). A copper electroless plating layer 5 is formed on the insulating layer 2 (e) and a copper electroplating layer 6 is formed on the copper electroless plating layer 5 (f). The surface of the obtained structure is grounded to accomplish a printed circuit board.

However, this method requires a high-level technique to manufacture a negative pattern using the mold and fill the negative pattern with a conductive material. Accordingly, the manufacturing process is inefficient and takes a long time. Furthermore, surface grinding is indispensable, and thus circuit precision is decreased.

### DISCLOSURE OF INVENTION

### Technical Problem

An object of the present invention is to provide a high-density and high-reliability printed circuit board with a circuit embedded in an insulating layer.

Another object of the present invention is to provide a method of manufacturing a printed circuit board, which uses a mold so as to eliminate a circuit manufacturing process for embedding, forms an insulating layer combined with a seed layer to omit a process for forming the seed layer and removes a complicated process such as surface grinding to simplify a manufacturing process.

### Solution to Problem

To achieve the above object, there is provided a method of manufacturing an embedded printed circuit board, comprising a first step of forming a first insulating layer having a seed layer formed on one side thereof and at least one metal pattern embedded therein; and a second step of laminating the first insulating layer and a base substrate with an inner circuit having a second insulating layer interposed between the first insulating layer and the base substrate.

The first step may further comprise a step al of forming a negative pattern on the first insulating layer with the seed layer formed on one side thereof using a mold; a step a2 of filling the negative pattern with a metal material. The step s2 may further comprise a step of performing chemical or physical etching to expose the seed layer. In this case, the thickness of the first insulating layer may equal to the thickness of a pattern of the mold. Furthermore, the thickness of the seed layer may be less than the thickness of the first insulating layer.

The step s2 may fill the metal material in the negative pattern through electroplating or electroless plating using the exposed seed layer.

The method may further comprise a step of forming roughness on the surface of the first insulating layer before or after the step s2 to improve laminating efficiency of the second insulating layer.

The second step may sequentially laminate the first insulating layer, the second insulating layer, and the base substrate with the inner circuit and apply heat and pressure to the laminated structure.

The method may further comprise a third step of removing the seed layer formed on one side of the first insulating layer after the second step. The method may further comprise a step of forming a via-hole in a predetermined region of the printed circuit board and filling the via-hole after the third step. The via-hole may be formed by coating photoresist on the printed circuit board and performing photolithography through expose, development and etching on the photoresist.

The following embedded printed circuit board may be obtained through the aforementioned manufacturing method.

The embedded printed circuit board comprises at least one metal pattern embedded in a first insulating layer; a second insulating layer formed under the first insulating layer; and a base substrate formed under the second insulating layer and having an inner circuit pattern embedded in the second insulating layer.

The embedded printed circuit board may further comprise a seed layer formed on the first insulating layer. The seed layer may be removed later.

The thickness of the metal pattern may not exceed the thickness of the first insulating layer. The embedded printed circuit board may further comprise a via-hole electrically connected to the inner circuit pattern embedded in the second insulating layer.

The foregoing and other objects, features, aspects and advantages of the present invention will become more apparent from the following detailed description of the present invention when taken in conjunction with the accompanying drawings.

### Advantageous Effects of Invention

According to the present invention, a printed circuit board with a circuit embedded in an insulating layer is provided, and thus a high-density and high-reliability printed circuit board can be achieved. Furthermore, since the printed circuit board is manufactured using a mold, a circuit manufacturing process for embedding, a process for forming a seed layer and a complicated process such as surface grinding are omitted so as to simplify the manufacturing process.

### BRIEF DESCRIPTION OF DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIGS. 1 and 2 illustrate conventional methods of manufacturing a printed circuit board;

FIGS. 3 and 4 illustrate methods of manufacturing a printed circuit board according to the present invention; and

FIG. 5 illustrates a process of forming a via-hole of a printed circuit board according to the present invention.

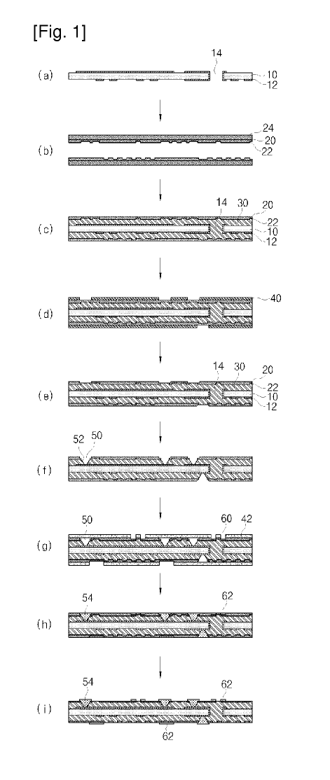

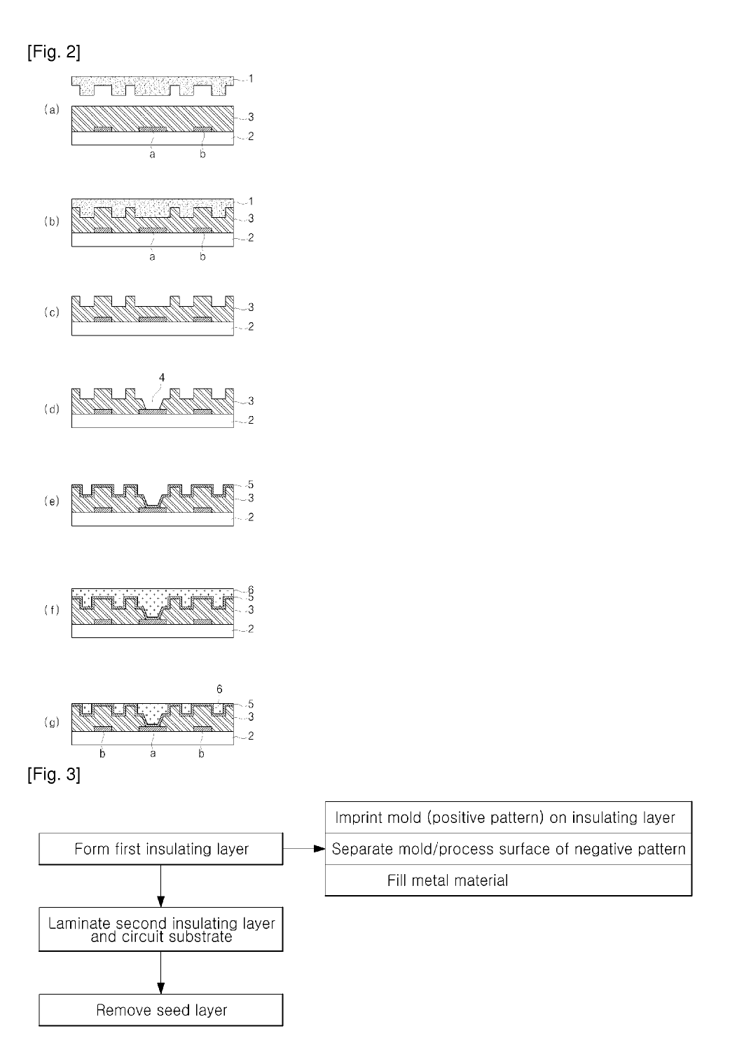

### BEST MODE FOR CARRYING OUT THE INVENTION

A method of manufacturing an embedded printed circuit board comprises a first step of forming a first insulating layer having a seed layer formed on one side thereof and at least one metal pattern embedded therein and a second step of laminating the first insulating layer and a base substrate with an inner circuit having a second insulating layer interposed between the first insulating layer and the base substrate. The seed layer may be removed or a via-hole forming step may be added.

The embedded printed circuit board manufactured by this method comprises at least one metal pattern embedded in a first insulating layer, a second insulating layer formed under the first insulating layer, and a base substrate formed under the second insulating layer and having an inner circuit pattern embedded in the second insulating layer.

### Mode for the Invention

The present invention will now be described more fully with reference to the accompanying drawings, in which exemplary embodiments of the invention are shown. Like reference numerals in the drawings like elements, and thus their description will be omitted. Though “First” and “Second” are used to explain various components, the components are not limited by the terms and the terms are used only to discriminate a component from another component.

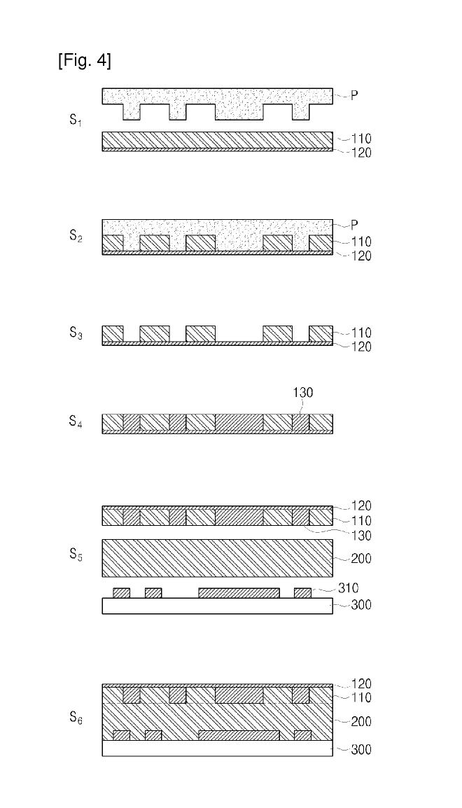

FIGS. 3 and 4 illustrate a method of manufacturing a printed circuit board according to the present invention.

The method of manufacturing a printed circuit board according to the present invention includes a first step of forming a first insulating layer having a seed layer formed on one side thereof and a metal pattern embedded therein and a second step of laminating the first insulating layer and a base substrate with an inner circuit having a second insulating layer interposed between the first insulating layer and the base substrate. After the second step, the seed layer may be removed or a via-hole forming step may be added.

### 1. Step of Forming First Insulating Layer

A first insulating layer 110 with a seed layer 120 formed on one side thereof is formed in step S1. A mold P with a predetermined positive circuit pattern is prepared and aligned with the first insulating layer 110. The pattern of the mold P may be formed through photolithography, laser processing or the like.

The mold P is placed on the first insulating layer 110 such that the positive circuit pattern of the mold P and the face of the first insulating layer 110 on which the seed layer 120 is not formed face each other and the mold P and the first insulating layer 110 are pressed against each other to imprint the circuit pattern of the mold P on the first insulating layer 110 in step S2. In this case, the maximum thickness of the circuit pattern of the mold P is limited to thickness of the first insulating layer 110. Furthermore, the thickness of the circuit pattern may equal to the thickness of the first insulating layer. In addition, the thickness of the seed layer 120 may be identical to or less than the thickness of the first insulating layer 110.

When the mold is separated from the first insulating layer 110, a negative pattern is formed on the first insulating layer 110 in step S3. A surface processing step such as chemical or physical surface processing may be additionally performed to expose the seed layer 120.

The negative pattern of the first insulating layer 110 is filled with a metal material in step S4.

The metal material may be filled in the negative pattern through electroplating and electroless plating using the seed layer 120 formed on one side of the first insulating layer 110. The negative pattern of the first insulating layer 110 is filled with the metal material to form a metal pattern 130. The thickness of the metal pattern 130 may equal to the thickness of the first insulating layer 110. Specifically, the thickness of the metal pattern 120 may be less than the thickness of the first insulating layer 110.

Particularly, the method may further include a step of forming roughness on the surface of the insulating layer 110 on which the seed layer is not formed so as to improve adhesiveness of the first insulating layer and a second insulating layer 200 which will be formed on the first insulating layer. The step of forming roughness may be included in any one of steps S1, S2, S3 and S4.

### 2. Step of Laminating Second Insulating Layer

The second insulating layer 200 and a base substrate 300 on which an inner circuit 310 is formed are arranged under the first insulating layer 110 in step S5. Then, the second insulating layer 200 and the base substrate 300 are heated and pressed to form a printed circuit board in step S6. A step of forming a via-hole in a predetermined region of the printed circuit board through photolithography and filling the via-hole may be added after step S6.

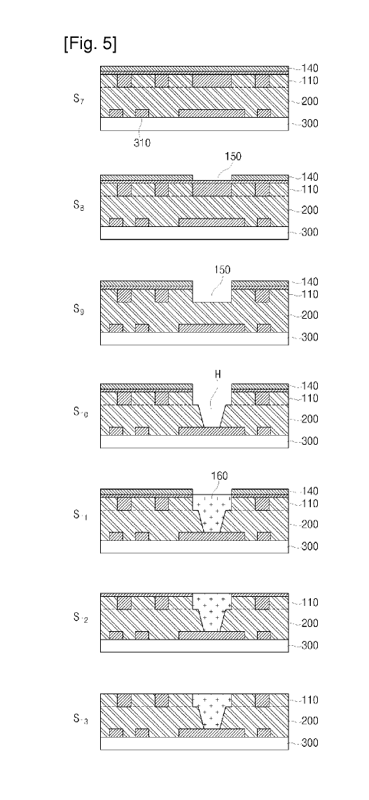

FIG. 5 illustrates a process of forming a via-hole in the printed circuit board formed in step S6 shown in FIG. 4.

Specifically, photoresist 140 is coated on the printed circuit board in step S7 and exposed, developed and etched to form a via-hole H in steps S8, 9 and 10. Then, the via-hole is filled with a metal material 160 to form a conductive path in steps S11 and S12. Thereafter, the seed layer may be removed in step S13.

The structure of the printed circuit board manufactured through above manufacturing process will now be explained.

According to an embodiment of the present invention, the printed circuit board may include at least one metal pattern embedded in the first insulating layer, the second insulating layer formed under the first insulating layer, and the base substrate having an inner circuit pattern embedded in the second insulating layer, which is obtained in step S6 of FIG. 4. That is, the printed circuit board has a two-level insulating layer. In this case, the seed layer may be formed on the first insulating layer. In addition, the seed layer may be removed after the conductive path is formed by forming the via-hole, as described above.

While the present invention has been particularly shown in and described with reference to exemplary embodiments thereof, it will be understood by those of ordinary skill in the art that various changes in form and details may be made therein without departing the spirit and scope of the present invention as defined by the following claims.

1. A method of manufacturing an embedded printed circuit hoard, comprising:
a first step of forming a first insulating layer having a seed layer formed on one side thereof and at least one metal pattern embedded therein; and
a second step of laminating the first insulating layer and a base substrate with an inner circuit having a second insulating layer interposed between the first insulating layer and the base substrate.

2. The method of claim 1, wherein the first step comprises:
a step a1 of forming a negative pattern on the first insulating layer with the seed layer formed on one side thereof using a mold;
a step a2 of filling the negative pattern with a metal material.

3. The method of claim 2, wherein the step s2 further comprises a step of performing chemical or physical etching to expose the seed layer.

4. The method of claim 2, wherein the thickness of the first insulating layer equals to the thickness of a pattern of the mold.

5. The method of claim 2, wherein the thickness of the seed layer is less than the thickness of the first insulating layer.

6. The method of claim 2, wherein the step s2 tills the metal material in the negative pattern through electroplating or electroless plating using the exposed seed layer.

7. The method claim 2, further comprising a step of forming roughness on the surface of the first insulating layer before or after the step s2.

8. The method of claim 2, wherein the second step sequentially laminates the first insulating layer, the second insulating layer, and the base substrate with the inner circuit and applies heat and pressure to the laminated structure.

9. The method of claim 2, further comprising a third step of removing the seed layer formed on one side of the first insulating layer after the second step.

10. The method of claim 9, further comprising a step of forming a via-hole in a predetermined region of the printed circuit board and filling the via-hole after the third step.

11. The method of claim 10, wherein the via-hole is formed by coating photoresist on the printed circuit board and performing photolithography through expose, development and etching on the photoresist.

12. An embedded printed circuit board comprising:
at least one metal pattern embedded in a first insulating layer;
a second insulating layer formed under the first insulating layer; and
a base substrate formed under the second insulating layer and having an inner circuit pattern embedded in the second insulating layer.

13. The printed circuit board of claim 12, further comprising a seed layer formed on the first insulating layer.

14. The printed circuit board of claim 12, wherein the thickness of the metal pattern does not exceed the thickness of the first insulating layer.

15. The printed circuit board of claim 14, further comprising a via-hole electrically connected to the inner circuit pattern embedded in the second insulating layer.

16. The method claim 3, further comprising a step of forming roughness on the surface of the first insulating layer before or after the step s2.

17. The method claim 4, further comprising a step of forming roughness on the surface of the first insulating layer before or after the step s2.

18. The method claim 5, further comprising a step of forming roughness on the surface of the first insulating layer before or after the step s2.

19. The method claim 6, further comprising a step of forming roughness on the surface of the first insulating layer before or after the step s2.
